(19) United States
(12) Patent Application Publication
(10) Pub. No.: US 2025/0063780 A1
(43) Pub. Date: Feb. 20, 2025

(54) Vertical Nano-Pillar Transistor Structures for 3-D ICS

(71) Applicant: Murata Manufacturing Co., Ltd., Kyoto (JP)

(72) Inventors: Sinan Goktepeli, Austin, TX (US); Kouassi Sebastien Kouassi, San Diego, CA (US)

(21) Appl. No.: 18/451,554

(22) Filed: Aug. 17, 2023

(51) Int. Cl. H01L 29/06; H01L 29/08; H01L 29/66; H01L 29/78

(52) U.S. Cl. CPC H01L 29/0673; H01L 29/0865; H01L 29/0882; H01L 29/66439; H01L 29/7851

(57) ABSTRACT

Nano-pillar field-effect transistor (FET) structure that include one or more of the following characteristics: vertical device structure and vertical current flow; vertically displaced source and drain regions; different nanowire/nanosheet geometries and dimensions for different nano-pillar embodiments; and/or body contacts made through wide nano-pillar structures. In addition, by utilizing layer transfer techniques, direct access to drain contacts of a nano-pillar FET structure is available, which enables a significant improvement in transistor performance (e.g., lower R_{ON} resistance, faster switching speed). An additional advantage of the novel nano-pillar FET structures is that available top and bottom contacts may be used in various 3-D integrated circuit structures, such as by using layer transfer and/or hybrid bonding.

### BACKGROUND

### (1) Technical Field

The present invention relates to three-dimensional integrated circuit structures and circuits.

### (2) Background

The electronics industry continues to strive for ever-increasing electronic functionality and performance in a wide variety of products, including (by way of example only) personal electronics (e.g., “smart” watches and fitness wearables), personal computers, tablet computers, wireless network components, televisions, cable system “set top” boxes, radar systems, and cellular telephones. Increased functionality and/or performance commonly translates to more transistors and other electronic components on an integrated circuit (IC) die. While the number of transistors per unit area of an IC die has increased over time as IC manufacturing process nodes have shrunk device dimensions, the two-dimensional (2-D) planar “footprint” of some IC dies has not decreased at the same rate, primarily owing to the use of more (albeit smaller) transistors to implement increased functionality and/or performance. The 2-D footprint of an IC die is one constraint on reducing the size of modules and circuit boards within products.

The performance of conventional 2-D ICs also may be limited in certain aspects due to the constraints of planar fabrication. For example, conventional 2-D metal-oxide-semiconductor field-effect transistor (MOSFET) ICs are susceptible to electro-static discharge (ESD) events and leakage currents. Another disadvantage of conventional 2-D MOSFET ICs is that the electrical contact to the gate often overlies the electrical contacts to the source and/or drain, causing parasitic capacitance problems. For example, FIG. 1 shows a stylized plan view of a prior art MOSFET 100 in which conductive source 102 and conductive drain 104 regions are interdigitated on a substrate or body 106. An overlying conductive gate layer 108 with a number of “fingers” (three are shown by way of example) is situated with the fingers located between the interdigitated projections of the source 102 and drain 104 regions. When biased by an appropriate voltage level, the gate layer 108 modulates conductive channels between the source 102 and drain 104 regions. Also shown is a drain-to-body tie 110. As may be appreciated, parasitic capacitance may arise due to the conductive gate layer 108 overlaying the conductive source 102 and drain 104 regions and by the proximity of the conductive source region 102 to the conductive drain region 104.

One approach to overcoming the limitations of conventional 2-D ICs is use of nanowire-based FETs. For example, FIG. 2 is a cross-sectional view of a prior art nanowire-based FET 200. One method of fabricating the structure shown in FIG. 2 starts with a substrate 202 (e.g., silicon) on which an array of silicon (Si) nanowire pillars 204 is formed, such as by masking and etching the substrate 202. A drain region 206 around each pillar 204, as well as source “caps” 208 on the exposed top of the pillars 204, are formed, such as by implantation of dopants. The drain regions 206 are subjected to a diffusion process to provide laterally diffused drains 210 under each pillar (shown as a dotted pattern for purposes of distinguishing the diffused drains 210 from the drain regions 206, but functionally the drain regions 206 and the diffused drains 210 are the same). A dielectric is formed on the vertical sides of the pillars 204, such as by converting the exposed Si to silicon dioxide (SiO₂). A first dielectric spacer layer 212 (e.g., silicon dioxide) is formed around the pillars 204, followed by formation of conductive gate material 214 (e.g., doped polysilicon) in a “gate-all-around” (GAA) configuration. A second dielectric spacer layer 216 is then formed around the pillars 204.

The above steps are typically performed in a “front-end-of-line” (FEOL) fabrication facility. A superstructure 220 may then be fabricated on the source-side of the completed FEOL structure, typically in a “back-end-of-line” (BEOL) fabrication facility. The superstructure 220 may include a source contact 222, a gate contact 224, and a drain contact 226, each comprising vias 228 and interconnecting portions of a metal layer 230.

Nanowire-based FETs overcome some of the limits of conventional 2-D ICs, in part because of their suitability for GAA architectures which provide improved electrostatic control over the channel and facilitate further reductions in transistor size while maintaining low leakage currents. However, some drawbacks remain, such as the proximity of the gate contact 224 to the source contact 222 and/or the drain contact 226. Accordingly, there is a need for improved nanowire-based FET structures. The present invention addresses this need.

### SUMMARY

The present invention encompasses nano-pillar field-effect transistor (FET) structures. Various embodiments include one or more of the following characteristics: vertical device structure and vertical current flow; vertically displaced source and drain regions; different nanowire/nanosheet geometries and dimensions for different nano-pillar embodiments; and/or body contacts made through wide nano-pillar structures. In addition, by utilizing layer transfer techniques, direct access to drain contacts of a nano-pillar FET structure is available, which enables a significant improvement in transistor performance (e.g., lower R_{ON} resistance, faster switching speed, better parasitic characteristics, etc.). An additional advantage of the novel nano-pillar FET structures is that available top and bottom contacts may be used in various 3-D integrated circuit structures, such as by using layer transfer and/or hybrid bonding.

One embodiment comprises a vertical nano-pillar FET, including a handle wafer, and an inverted nano-pillar FET including a superstructure bonded to a surface of the handle wafer. This embodiment may also include one or more nano-pillar structures each having a first end, a middle portion, and a second end; at least one source cap, each source cap in electrical contact with the first end of an associated nano-pillar structure of the one or more nano-pillar structures; a gate layer surrounding the middle portion of the one or more nano-pillar structures; a drain region in electrical contact with the second end of the one or more one nano-pillar structures.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1 shows a stylized plan view of a prior art MOSFET in which conductive source and conductive drain regions are interdigitated on a substrate or body.

FIG. 2 is a cross-sectional view of a prior art nanowire-based FET.

FIG. 3A is a cross-sectional diagram of an early stage of vertical nano-pillar fabrication.

FIG. 3B is a cross-sectional diagram of drain and source formation for a vertical nano-pillar structure.

FIG. 3C is a cross-sectional diagram of an optional drain diffusion stage for a vertical nano-pillar structure.

FIG. 3D is a plan view of an array of nano-pillars comprising approximately cylindrical Si nanowires.

FIG. 3E is a plan view of an array of nano-pillars comprising fin-like Si nanosheets.

FIG. 3F is a plan view of an array of nano-pillars comprising fin-like Si nanosheets spanned by a common fin-like Si nanosheet.

FIG. 3G is a cross-sectional diagram of a further FEOL fabrication stage for a vertical nano-pillar structure.

FIG. 3H is a cross-sectional diagram of a BEOL fabrication stage for a vertical nano-pillar structure, showing one example of a superstructure.

FIG. 3I is a cross-sectional diagram of a first part of an SLT fabrication stage for a vertical nano-pillar structure.

FIG. 3J is a cross-sectional diagram of a second part of an SLT fabrication stage for a vertical nano-pillar structure, showing that the initial substrate has been removed.

FIG. 3K is a cross-sectional diagram of a third part of an SLT fabrication stage for a vertical nano-pillar structure, showing a new structure formed on the new top of the IC structure by a backside process.

FIG. 3L is a cross-sectional diagram of one embodiment of an SLT vertical nano-pillar structure showing a new backside structure that includes a drain contact connecting to the drain region.

FIG. 4 is a cross-sectional diagram of a vertical nano-pillar structure with undiffused drain regions.

FIG. 5 is a cross-sectional diagram of a vertical nano-pillar FET switch.

FIG. 6A is a cross-sectional diagram of an early stage of fabrication for a vertical nano-pillar FET having self-aligned source and drain caps.

FIG. 6B is a cross-sectional diagram of a next stage of vertical nano-pillar FET fabrication.

FIG. 6C is a cross-sectional diagram of a vertical nano-pillar FET with self-aligned source and drain caps.

FIG. 6D is a cross-sectional diagram of a vertical nano-pillar FET with self-aligned source and drain caps and added dielectric and gate layers.

FIG. 6E is a cross-sectional diagram of a BEOL fabrication stage for a vertical nano-pillar FET structure having self-aligned source and drain caps, showing one example of a superstructure.

FIG. 6F is a cross-sectional diagram of a first part of an SLT fabrication stage for a vertical nano-pillar structure having self-aligned source and drain caps.

FIG. 6G is a cross-sectional diagram of a second part of an SLT fabrication stage for a vertical nano-pillar structure having self-aligned source and drain caps.

FIG. 6H is a cross-sectional diagram of a third part of an SLT fabrication stage for a vertical nano-pillar structure.

FIG. 7 is a top plan view of a substrate 700 that may be, for example, a printed circuit board or chip module substrate (e.g., a thin-film tile).

FIG. 8 is a process flow chart showing a method for fabricating a vertical nano-pillar FET.

FIG. 9 is a process flow chart showing a method for fabricating a vertical nano-pillar FET having self-aligned source and drain caps.

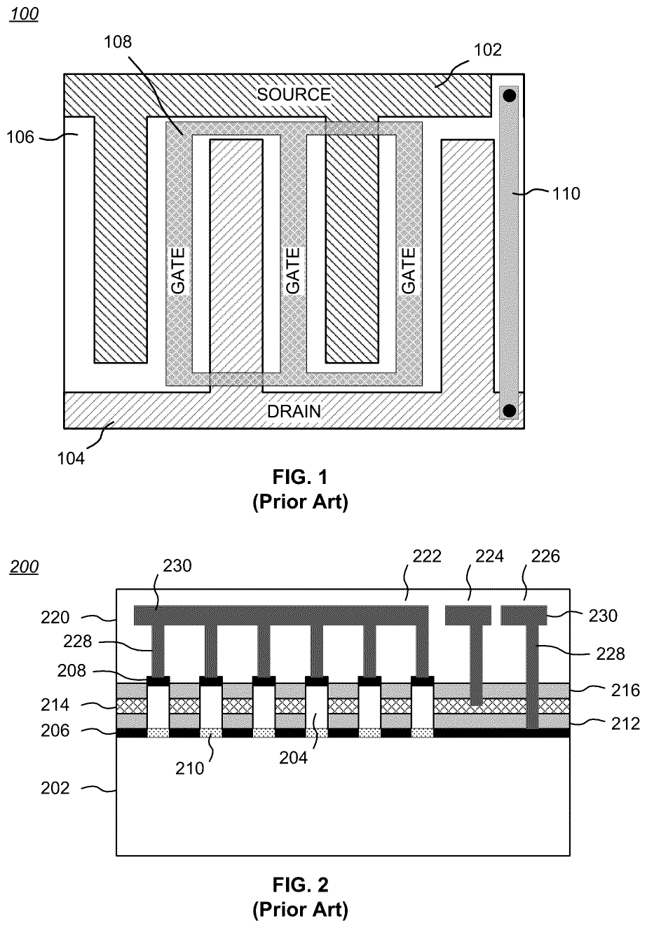

Like reference numbers and designations in the various drawings indicate like elements.

### DETAILED DESCRIPTION

The present invention encompasses nano-pillar field-effect transistor (FET) structures. Various embodiments include one or more of the following characteristics: vertical device structure and vertical current flow; vertically displaced source and drain regions; different nanowire/nanosheet geometries and dimensions for different nano-pillar embodiments; and/or body contacts made through wide nano-pillar structures. In addition, by utilizing layer transfer techniques, direct access to drain contacts of a nano-pillar FET structure is available, which enables a significant improvement in transistor performance (e.g., lower R_{ON} resistance, faster switching speed, better parasitic characteristics, etc.). An additional advantage of the novel nano-pillar FET structures is that available top and bottom contacts may be used in various 3-D integrated circuit structures, such as by using layer transfer and/or hybrid bonding.

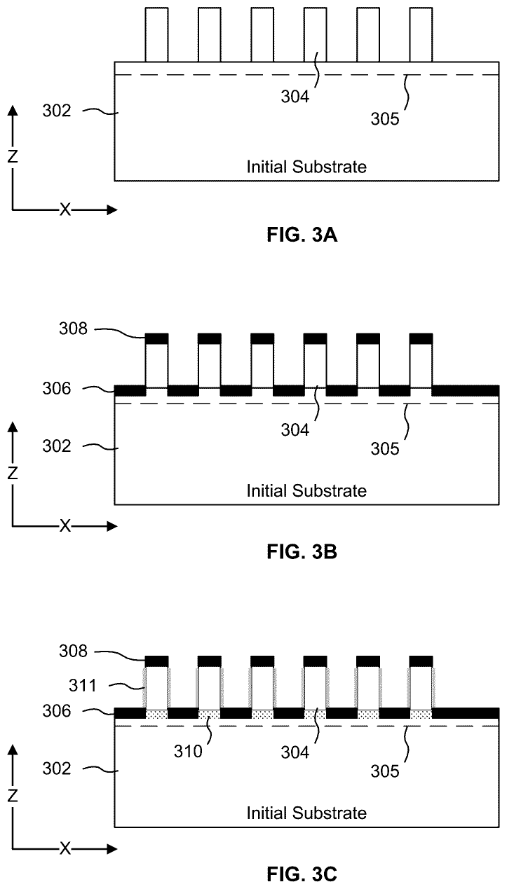

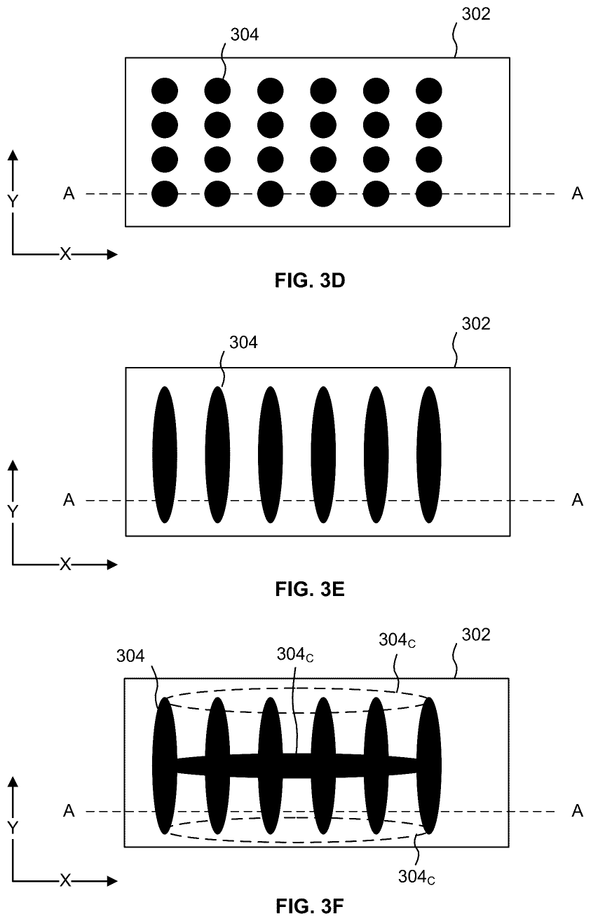

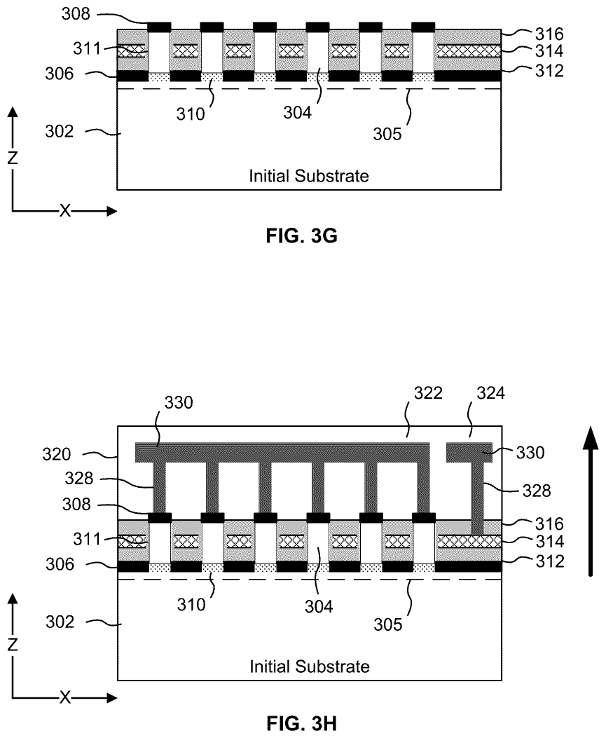

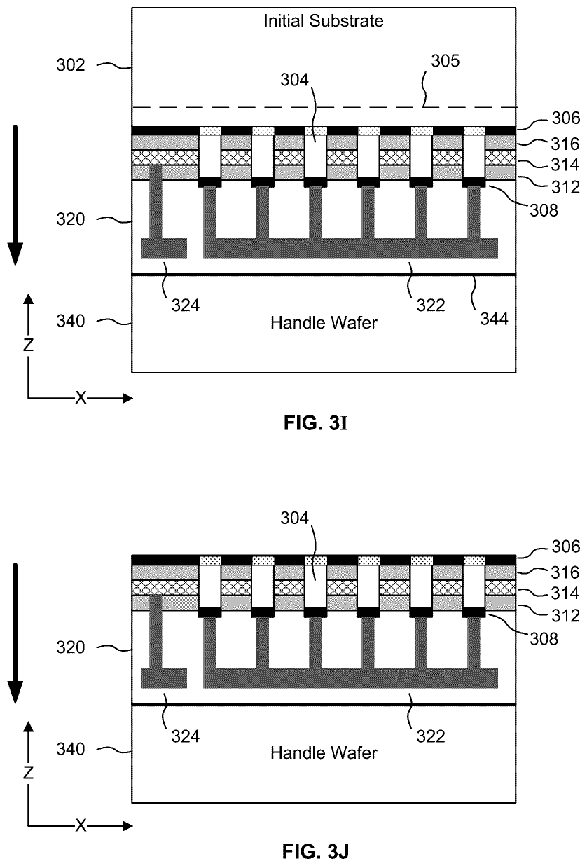

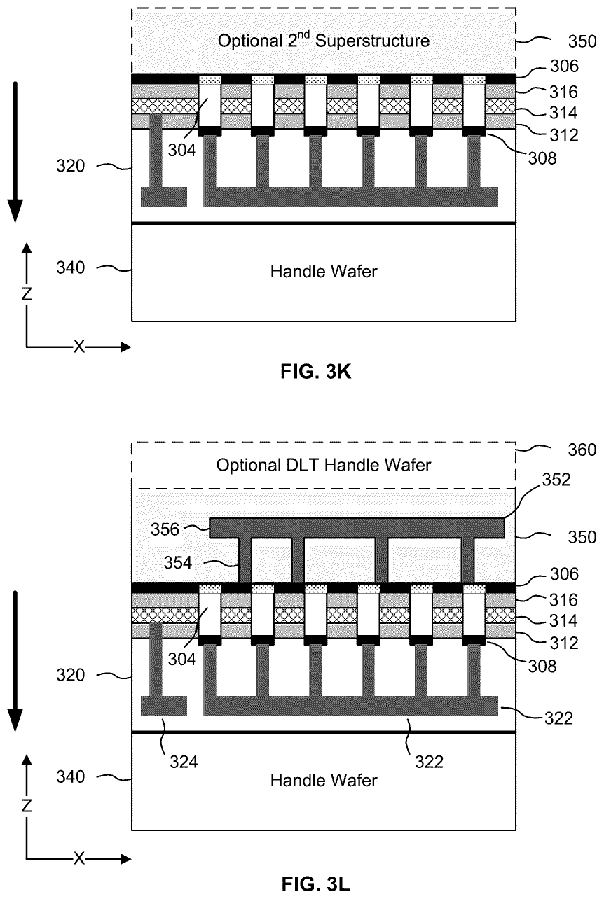

FIGS. 3A-3H show selected steps and options for making a nano-pillar FET structure in accordance with the present invention. FIG. 3A is a cross-sectional diagram of an early stage of vertical nano-pillar fabrication. The structure shown in FIG. 3A starts with an initial substrate 302 (e.g., silicon, germanium, SiGe, etc.) on which an array of silicon (Si) nano-pillars 304 is formed, such as by masking and etching the initial substrate 302, by masking and epitaxially growing the Si nano-pillars 304 upon the initial substrate 302, or any other suitable technique for making such nano-pillars. In one example embodiment, the size of the nano-pillars 304 was typically about 5 nm in the X dimension (i.e., about 5 nm in diameter if nanowires are used for the nano-pillars) and 20-40 nm in the Z dimension (i.e., height), but other sizes for the nano-pillars 304 may be used.

It may be beneficial in some embodiments to create a separation layer 305 in the initial substrate 302 before forming the Si nano-pillars 304, for purposes which will become clear below. The separation layer 305 may be formed, for example, by implanting ions (most commonly hydrogen ions) to form a layer of weakening bubbles at a proscribed depth, which allows the portion of the initial substrate 302 below the separation layer 305 to be readily removed. In some embodiments, it may be useful to use a silicon-on-insulator (SOI) substrate so that the buried oxide (BOX) layer may be used as an etch stop layer.

FIG. 3B is a cross-sectional diagram of drain and source formation for a vertical nano-pillar structure. A drain region 306 is formed within the substrate around the base of each nano-pillar 304, and source caps 308 are formed on the exposed tops of the nano-pillars 304, such as by ion implantation of a dopant, by plasma or solid-state diffusion doping, or by epitaxial growth. The portion of the nano-pillars 304 between drain region 306 and the source caps 308 serves as the FET conduction channel.

FIG. 3C is a cross-sectional diagram of an optional drain diffusion stage for a vertical nano-pillar structure. In some embodiments, the drain regions 306 may be subjected to a diffusion process to provide laterally diffused drains 310 under each nano-pillar 304 (shown as a dotted pattern for purposes of distinguishing the diffused drains 310 from the drain regions 306, but functionally the drain regions 306 and the diffused drains 310 are the same). For suitably sized nano-pillars 304, the diffused drains 310 cover the substrate-side of the nano-pillars 304 opposite the source caps 308. For larger (in the X dimension) nano-pillars 304, there may be an underlying region near the middle of the nano-pillars 304 which remains unchanged after the diffusion process. That region will correspond to a device body, similar to a planar transistor, which may be left floating in some embodiments or may be connected as a body tied/contacted terminal in other embodiments.

A dielectric coating 311 may be formed on the vertical sides of the nano-pillars 304, such as by converting the exposed Si to silicon dioxide (SiO₂) or depositing a high dielectric constant (High-k) material using, for example, chemical vapor deposition (CVD) or plasma-enhanced CVD (PECVD). A High-k material may be used in conjunction with a metal gate, so-called HKMG technology. The dielectric coating 311 may be formed before or after the optional drain diffusion stage.

FIG. 3D is a plan view of an array of nano-pillars 304 comprising approximately cylindrical Si nanowires. However, embodiments of the invention are not limited to nanowire-type nano-pillars 304. For example, FIG. 3E is a plan view of an array of nano-pillars 304 comprising fin-like Si nanosheets. As another example, FIG. 3F is a plan view of an array of nano-pillars 304 comprising fin-like Si nanosheets spanned by a common fin-like Si nanosheet 304c. Note that more than one common fin-like Si nanosheet 304c may be used, such as spanning the top, middle, and bottom (with respect to the Y dimension) of the other nano-pillars 304; example additional common fin-like Si nanosheets 304c are shown in dashed outline. Note also that the cross-sectional view of FIG. 3C and similar figures is taken along line A-A in each of FIGS. 3D-3F, and hence looks the same despite differences in nano-pillar configuration. As should be clear to one of ordinary skill in the art, not all nano-pillars 304 in a particular IC need have the same shape, and other geometries and configurations of nano-pillars 304 may be used, including combinations of nano-pillar types (e.g., cylindrical and fin). Other packing arrangements of nano-pillars 304 may be used—for example, FIG. 3D shows square packing, but hexagonal packing or other arrangements may also be used.

In general, nanosheet structures exhibit lower resistance and higher current draw capability compared to nanowire structures, and accordingly may be preferred for many embodiments. For lowest resistance and highest current draw capability, a configuration with one or more common fin-like Si nanosheets 304c, as in FIG. 3F, may be preferred.

FIG. 3G is a cross-sectional diagram of a further FEOL fabrication stage for a vertical nano-pillar structure. A first dielectric spacer layer 312 (e.g., silicon dioxide) is formed around the nano-pillars 304, followed by formation of gate layer 314 (e.g., a layer of doped polysilicon or a metal) in a “gate-all-around” (GAA) configuration. A second dielectric spacer layer 316 is then formed around the nano-pillars 304. While the illustrated example shows the source caps 308 as protruding above the upper surface of the second dielectric layer 316, the upper surfaces of the source caps 308 may be co-planer with the upper surface of the second dielectric layer 316.

The illustrated structure operates as a FET when the drain region 306 and the source caps 308 are connected to suitable voltage potentials (e.g., a system voltage VDD and circuit ground, respectively) and a suitable gate voltage is applied to the gate layer 314. The illustrated FET structure may be operated as an enhancement-mode device or depletion-mode device, depending on the dopants selected, and may be implemented as an N-type FET or a P-type FET, again depending on the selection of materials used in fabrication.

The above steps are typically performed in an FEOL fabrication facility. A superstructure may then be fabricated on the source-side of the completed FEOL structure, typically in a BEOL fabrication facility. For example, FIG. 3H is a cross-sectional diagram of a BEOL fabrication stage for a vertical nano-pillar structure, showing one example of a superstructure 320. The superstructure 320 may include a source contact 322 coupled to the source regions 308 and a gate contact 324 coupled to the gate region 314. The source contact 322 and the gate contact 324 may each comprise vias 328 and interconnecting portions of at least one metal layer 330. The source caps 308 may be subjected to silicidation to facilitate electrical connection with the source contact 322.

In exemplary embodiments of the structure shown in FIG. 3H made using conventional CMOS fabrication processes, the dimensions of the nano-pillars 304 in the X dimension may be in the range of about 2-10 nm, while the Z dimension of the nano-pillars 304 may be in the range of about 20-40 nm. However, other dimensions may be used.

The gate length for each nano-pillar 304 is the Z dimension of the associated gate region 314 (note that FIG. 3H and similar figures are not to scale—for example, the Z heights of the dielectric spacer layers 312, 316 are generally much thinner than the Z height of the gate layer 314). In general, a shorter gate length means that the charge carrier travels from the source to drain in a shorter time, which increases switching speed. Conversely, a longer gate length means that there is a longer tunneling distance through the FET channel between source and drain, thus reducing the risk of voltage breakdown, and accordingly the FET exhibits better voltage handling capability. The gate length also impacts gate capacitance, which impacts FET switching speed-longer gate lengths exhibit increased gate capacitance and thus slower switching speeds compared to shorter gate lengths.

It should be noted that the Z dimension of the first and second dielectric spacer layers 312, 316 and of the gate layer 314 may be quite precisely controlled, typically within a tolerance of 5 atoms or less per layer, such as by using atomic layer deposition (ALD) or the like. Control of these Z dimensions allows fine control of the device channel length and of parasitic capacitance between the three terminals of the FET device.

As should be clear, a wide variety of FET types may be fabricated with the methods described above (including NMOS, PMOS, and/or CMOS FETs, and enhancement mode or depletion mode transistor devices) by selection of substrate active area material, dopants, and other materials.

In the following steps, a single-layer transfer (SLT) process may be used to expose the drain region 306. For example, FIG. 3I is a cross-sectional diagram of a first part of an SLT fabrication stage for a vertical nano-pillar structure. Essentially, the top of the nano-pillar structure shown in FIG. 3H is bonded to a handle wafer 340, inverting the nano-pillar structure-note the direction of the orientation arrow in FIG. 3H compared to FIG. 3G. An exaggerated bond line 344 denotes the common bonding surfaces of the vertical nano-pillar structure and the handle wafer 340. Note that the handle wafer 340 may be a simple host substrate or may include active and/or passive circuitry (e.g., in and on the non-bonding surface).

After bonding, the initial substrate 302 is removed partially or completely, such as by grinding, chemical or ion etching, chemical separation, or grinding and chemical-mechanical polishing (CMP) to expose the backside of the nano-pillar structure. If a separation layer 305 is used, then the bulk of the initial substrate 302 may be separated off. Any remaining portion of the initial substrate 302 that may need to be removed may be removed by one of the above-mentioned processes. FIG. 3J is a cross-sectional diagram of a second part of an SLT fabrication stage for a vertical nano-pillar structure, showing that the initial substrate 302 has been removed, fully exposing the backside of the structure.

The complete or even partial removal of the initial substrate 302 enables an ability to fabricate a second superstructure on the “new” top of the IC structure (i.e., the backside or drain region 306 side of the nano-pillars 304) that may be readily connected to at least the drain region 306. For example, FIG. 3K is a cross-sectional diagram of a third part of an SLT fabrication stage for a vertical nano-pillar structure, showing a new superstructure 350 formed on the new top of the IC structure by a backside process. The new superstructure 350 may be fabricated in a BEOL process or a post-BEOL fabrication process (e.g., as part of outsourced semiconductor assembly and test, “OSAT”), and may include electrical connections, active and/or passive devices, filters, sensors, etc. In some embodiments, the new superstructure 350 may include an entire IC bonded to the exposed backside of the nano-pillar structure and containing active and/or passive circuitry.

For example, FIG. 3L is a cross-sectional diagram of one embodiment of an SLT vertical nano-pillar structure showing a new backside superstructure 350 that includes a drain contact 352 connecting to the drain region 306. The drain contact 352 comprises vias 354 and at least one metal layer 356. The drain contact 352 may be made by conventional processes, such as by forming one or more layers of inter-layer dielectric (ILD) on the backside surface, masking and etching to form voids in the ILD for the vias 354, filling the voids with conductive material (e.g., a metal), and forming at least one metal layer 356 to connect the vias 354.

The result is that the drain contact 352 is located relatively distant from both the source contact 322 and the gate contact 324, thus reducing parasitic capacitance between the regions. Note that since the drain region 306 is widespread and diffused adjacent the nano-pillars 304, there is an insignificant risk of misalignment in making electrical contact to the drain region 306 for suitably sized nano-pillars 304.

Note that while FIG. 3L shows multiple nano-pillars 304 coupled in parallel between the drain contact 352 and the source contact 322, in some embodiments each nano-pillar 304 may be part of a separately connected FET having a dedicated (not shared) drain contact 352 and a dedicated source contact 322. Such configurations may require forming a diffused drain cap for each nano-pillar 304 as in FIG. 3G, then removing some or all of the drain material around each nano-pillar 304 to isolate the drains of the FETs and subdividing the gate layer 314 to form distinctly controlled FETs. As another example, some embodiments may include combinations of nano-pillars 304 and source/drain contacts fabricated within the same IC die such that some FETs comprise a single nano-pillar 304 with a dedicated drain contact 352, a dedicated source contact 322, and a dedicated gate, while other FETs comprise multiple nano-pillars 304 having shared drain contacts 352, source contacts 322, and gates. Multi-pillar FETs may be used to carry higher currents than single-pillar FETs.

Note that the above example shows single-layer transfer, where the handle wafer 340 becomes a permanent substrate for the bonded nano-pillar structure. However, layer transfer may be permanent or temporary, such as where the structure shown in FIG. 3L is subjected to a double-layer transfer (DLT) process. One example DLT process involves bonding a second handle wafer 360 (shown in FIG. 3L in dashed outline) to the exposed top (with respect to the page) of the illustrated structure and removing the first handle wafer 340, thus positioning the source contact 322 and the gate contact 324 close to a “new” top-surface of the vertical nano-pillar structure, while maintaining the drain contact 352 at a distance.

Further note that the drain region 306 and source caps 308 are arbitrarily labeled “drain” and “source”; the function of those elements may be reversed, such that in some embodiments, the region 306 may be the FET source and the caps 308 may be the FET drain.

A variant nano-pillar structure is particularly suited for use as a high voltage transistor device by reducing or even eliminating the risk of impact ionization at the gate. Embodiments of the variant nano-pillar structure do not form laterally diffused drains 310 under each nano-pillar—that is, the drain diffusion step is skipped.

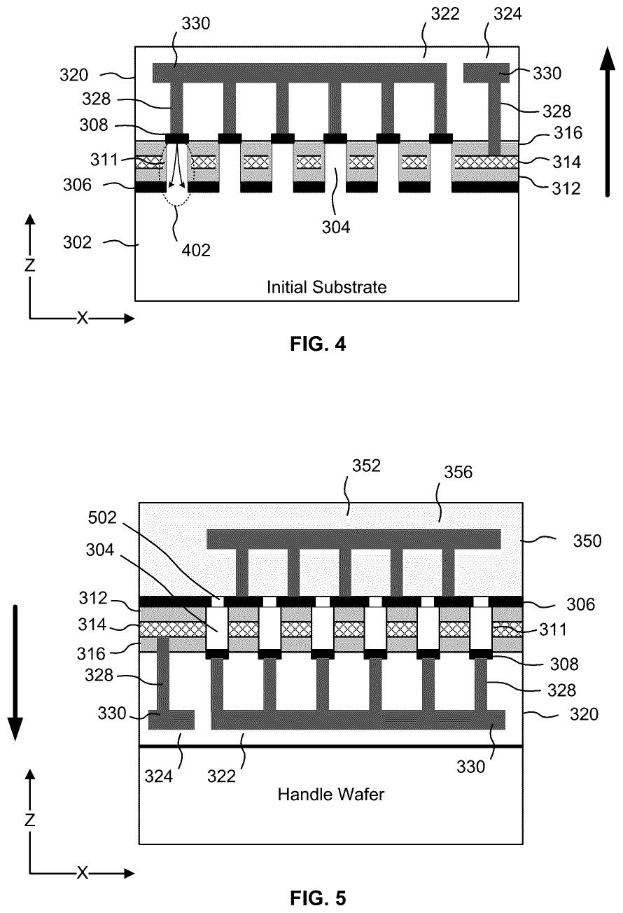

For example, FIG. 4 is a cross-sectional diagram of a vertical nano-pillar structure with undiffused drain regions 306. However, in some embodiments, there may be some diffusion of the drain regions 306 to partially extend beneath the bottoms of the nano-pillars 304 to improve the current path to the drain regions 306. In example embodiments of the structure shown in FIG. 4 made using conventional CMOS fabrication processes, the gate length LGATE of the nano-pillars 304 may be in the range of about 100-350 nm, and the X dimension of the nano-pillars 304 may be in the range of about 20-300 nm.

In operation, as electrons traverse from the source caps 308 to the drain regions 306, the electrons have to turn to the outer edges of the nano-pillars 304 in order to enter the drain region 306 (see arrow within dashed circle 402). The enforced turn reduces the energy of the electrons and moves the drain junction away from the gate layer 314, which reduces or even eliminates the risk of impact ionization at the gate. A lower risk of impact ionization damage at the gate means a lower risk of hot carrier injection (HCl). Accordingly, a vertical nano-pillar structure without diffused drains can withstand higher source-drain voltages than a structure having diffused drains.

Note that the vertical nano-pillar structure of FIG. 4 may be used as a conventionally-oriented IC if top-side contacts are made to the drain region 306, as in FIG. 2, but may also be used in an SLT process as described above to fabricate an embodiment similar to the structure shown in FIG. 3L.

Another variation of a vertical nano-pillar structure may be configured as space-saving switch. For example, FIG. 5 is a cross-sectional diagram of a vertical nano-pillar FET switch. While similar in most aspects to the vertical nano-pillar structure shown in FIG. 3L, in the embodiment shown in FIG. 5, the drain region 306 is not diffused to form a closed section at the bottom of each nano-pillar 304. An undiffused region near the drain-side end of the each nano-pillar 304 may be coupled to a body contact 502. This undiffused region corresponds to the transistor body in a planar FET configuration and can be controlled separately, similarly to a standard FET, by adding an additional terminal that can be tied to another terminal (e.g., source) or to a bias voltage or circuit ground (making a body-tied FET) or left floating (making a floating-body FET).

In example embodiments of the structure shown in FIG. 5 made using conventional CMOS fabrication processes, the gate length LGATE of the nano-pillars 304 may be in the range of about 100-250 nm, and the X dimension of the nano-pillars 304 may be in the range of about 20-100 nm.

The common drain or source configuration of the previous examples is particularly useful for a number of applications, such as FET device stacking to withstand high voltages in an RF switch. Another variation of a vertical nano-pillar structure provides for self-aligned source and drain contacts for the nano-pillars, in contrast to the broad drain regions for the embodiments shown in FIGS. 3L, 4, and 5. An advantage of a self-aligned structure is the case of individually connecting each terminal for each FET structure, thereby enabling individual nano-pillar FETs to have different functions, if desired. A self-aligned configuration is particularly beneficial for implementing digital circuitry, such as logic gates and control circuits.

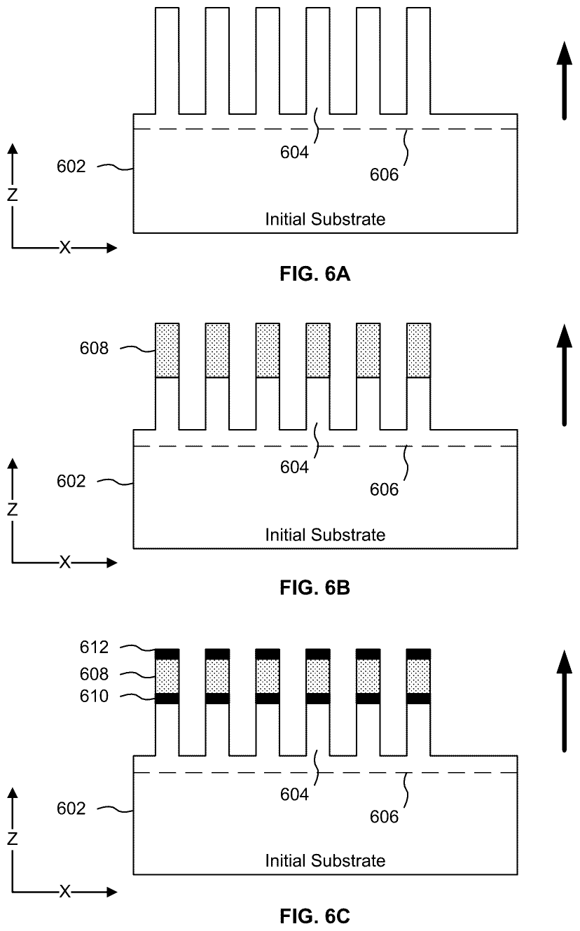

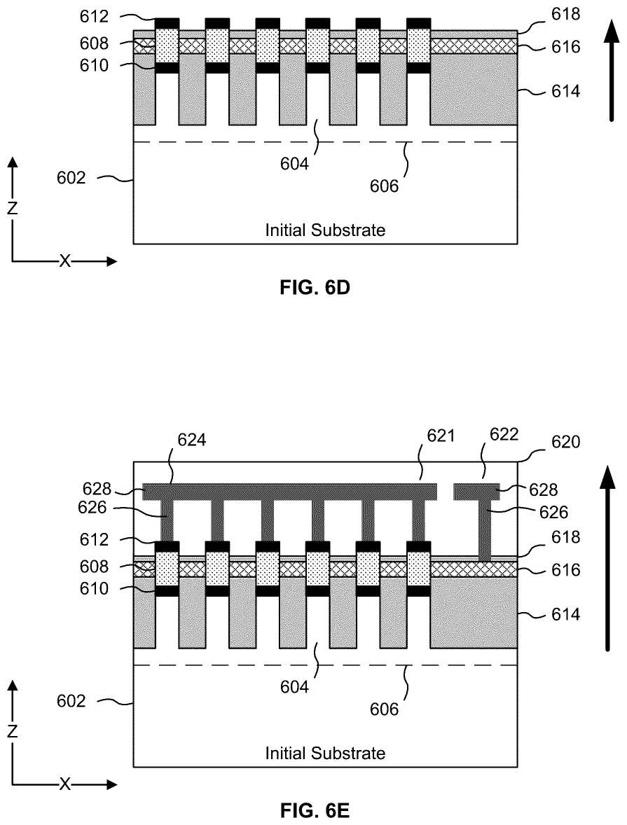

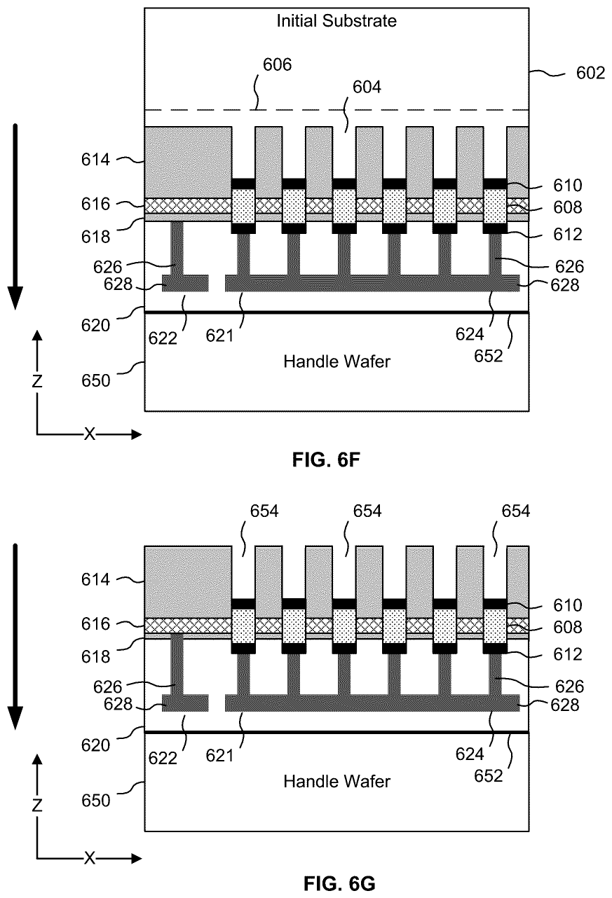

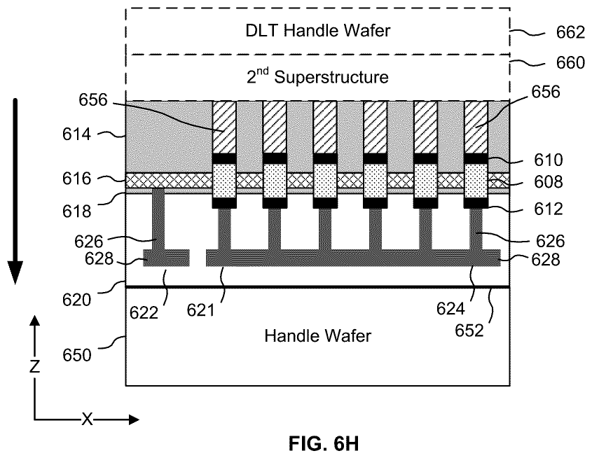

FIGS. 6A-6H show one example of selected steps and options for making a nano-pillar FET structure with self-aligned source and drain caps. FIG. 6A is a cross-sectional diagram of an early stage of fabrication for a vertical nano-pillar FET having self-aligned source and drain caps. The structure shown in FIG. 6A starts with an initial substrate 602 (e.g., silicon) on which an array of silicon (Si) nano-pillars 604 is formed, such as by masking and etching the initial substrate 602, by masking and epitaxially growing the Si nano-pillars 604 upon the initial substrate 602, or any other suitable technique for making such nano-pillars. In one example embodiment, the nano-pillars 604 were typically about 5 nm in diameter and 20-40 nm in height, but other dimensions for the nano-pillars 604 may be used. It may be beneficial in some embodiments to create a separation layer 606 in the initial substrate 602 before forming the Si nano-pillars 604.

FIG. 6B is a cross-sectional diagram of a next stage of vertical nano-pillar FET fabrication. In some embodiments, a suitable dopant is introduced within the nano-pillars 604 to form a channel region 608 within the upper portions of the nano-pillars 604. For example, the dopant may be introduced by ion implantation or the like, in sufficient concentration to alter the electrical conductivity properties of the channel region 608. In other embodiments, the nano-pillars 604 need not be doped if suitable FET performance can be achieved using intrinsic (undoped) silicon. For purposes of the illustrated example, it is assumed that channel region 608 has been doped.

FIG. 6C is a cross-sectional diagram of a vertical nano-pillar FET with self-aligned source and drain caps. A suitable dopant is implanted (by ion implantation or the like) within the nano-pillars 604 to form a drain cap 610 for each of the nano-pillars 604 at a desired depth (in the Z dimension) within the nano-pillars 604. A suitable dopant is also implanted (by ion implantation or the like) within the nano-pillars 604 to form a source cap 612 for each of the nano-pillars 604 at a desired depth (in the Z dimension) within the nano-pillars 604. Accordingly, each nano-pillar 604 includes a conduction channel 608 separating an associated drain cap 610 and an associated source cap 612. The two steps of implantation may be performed as successive steps of one process stage.

FIG. 6D is a cross-sectional diagram of a vertical nano-pillar FET with self-aligned source and drain caps and added dielectric and gate layers. A first dielectric spacer layer 614 (e.g., silicon dioxide) is formed around the nano-pillars 604, followed by formation of gate layer 616 (e.g., a layer of doped polysilicon) in a “gate-all-around” configuration. A second dielectric spacer layer 618 is then formed around the nano-pillars 604. The source caps 612 remain exposed. While the illustrated example shows the source caps 612 as protruding above the upper surface of the second dielectric layer 618, the upper surfaces of the source caps 612 may be coplanar with the upper surface of the second dielectric layer 618.

The illustrated structure operates as a FET when the drain caps 610 and the source caps 612 are connected to suitable voltage potentials and a suitable gate voltage is applied to the gate layer 616. The illustrated FET structure may be operated as an enhancement-mode device or depletion-mode device, depending on the dopants selected, and may be implemented as an N-type FET or a P-type FET, again depending on the selection of materials used in fabrication.

The above steps are typically performed in an FEOL fabrication facility. A superstructure may then be fabricated on the source-side of the completed FEOL structure, typically in a BEOL fabrication facility. For example, FIG. 6E is a cross-sectional diagram of a post-BEOL fabrication stage for a vertical nano-pillar FET structure having self-aligned source and drain caps, showing one example of a superstructure 620. The superstructure 620 may include a source contact 621 coupled to the source caps 612 and a gate contact 622 coupled to the gate region 616. The source contact 621 and the gate contact 622 may each comprise vias 626 and interconnecting portions of at least one metal layer 628. The source caps 612 may be subjected to silicidation to facilitate electrical connection with the source contact 621.

As should be clear, a wide variety of FET types may be fabricated with the methods described above (including NMOS, PMOS, and/or CMOS FETs, and enhancement mode or depletion mode transistor devices) by selection of substrate active area material, dopants, and other materials.

In following steps, an SLT process may be used to expose the drain caps 610. For example, FIG. 6F is a cross-sectional diagram of a first part of an SLT fabrication stage for a vertical nano-pillar structure having self-aligned source and drain caps. Essentially, the top of the nano-pillar structure shown in FIG. 6E is bonded to a handle wafer 650, inverting the nano-pillar structure-note the direction of the orientation arrow in FIG. 6F compared to FIG. 6E. An exaggerated bond line 652 denotes the common bonding surfaces of the vertical nano-pillar structure and the handle wafer 650. Note that the handle wafer 650 may be a simple host substrate or may include active and/or passive circuitry (e.g., in and on the non-bonding surface).

FIG. 6G is a cross-sectional diagram of a second part of an SLT fabrication stage for a vertical nano-pillar structure having self-aligned source and drain caps. After bonding, the initial substrate 602 is removed partially or completely, such as be grinding, chemical or ion etching, chemical separation, or chemical-mechanical polishing (CMP) to expose the backside of the nano-pillar structure. If a separation layer 606 is used, then the bulk of the initial substrate 602 may be separated off. Any remaining portion of the initial substrate 602 (including Si nano-pillars 604 up to the drain caps 610) that may need to be removed may be removed, such as by chemical or ion etching, taking care to not remove the drain caps 610, such as by using a dopant for the drain caps 610 that is etchant resistant. A suitable etchant might be tetramethylammonium hydroxide (TMAH) and/or potassium hydroxide (KOH). As a result, voids 654 will be formed where a part of the Si nano-pillars 604 has been removed.

FIG. 6H is a cross-sectional diagram of a third part of an SLT fabrication stage for a vertical nano-pillar structure. The illustrated example shows that the initial substrate 602 has been removed and a filler of contact material (e.g., a metal) has been added to be in electrical contact with the drain caps 610 and fill the voids 654 of FIG. 6G above the drain caps 610, thus forming drain contacts 656. A CMP step may be added to planarize the top surface (with respect to the page) of the structure. Further steps may be performed to connect the exposed drain contacts 656 to other circuit elements and/or ICs. Such further steps may be performed in a BEOL process or a post-BEOL fabrication process (e.g., as part of OSAT), and may include electrical connections to active and/or passive devices, filters, sensors, etc. In some embodiments, the vertical nano-pillar structure of FIG. 6H may be bonded to an entire IC containing active and/or passive circuitry. The result is that the drain contacts 656 are located relatively distant from both the source contact 621 and the gate contact 622, thus reducing parasitic capacitance between the regions

Note that the example shown in FIGS. 6A-6H depicts single-layer transfer. However, a double layer transfer process may be applied as well. For example, in FIG. 6H, a second superstructure 660 (shown in FIG. 6H in dashed outline) may be formed in contact with the exposed drain contacts 656, and a second handle wafer 662 (shown in FIG. 6H in dashed outline) may be attached to the second superstructure 660. The first handle wafer 650 would generally be removed, thus positioning the source contact 621 and the gate contact 622 close to a “new” top-surface of the vertical nano-pillar structure, while maintaining the drain contacts 656 at a distance.

Note that the structure shown in FIG. 6H, with multiple remnants of the nano-pillars 604 (see FIG. 6F) each comprising a self-aligned drain cap 610, a channel region 608, and a source cap 612, is particularly well suited for subdividing the gate layer 616 to form distinctly controlled FETs. As another example, some embodiments may include combinations of nano-pillar remnants and source/drain contacts fabricated within the same IC die such that some FETs comprise a single nano-pillar remnant with a dedicated drain cap 610, a dedicated source cap 612, and a dedicated gate, while other FETs comprise nano-pillar remnants having electrically-connected drain caps 610, source caps 612, and gates.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

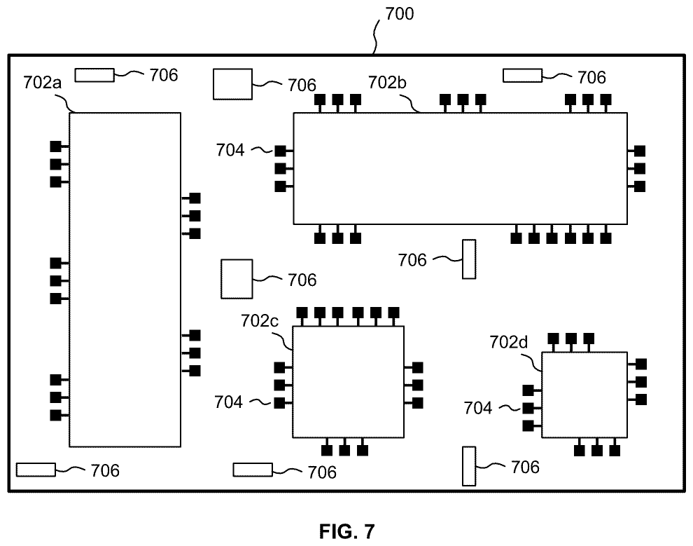

As one example of further integration of embodiments of the present invention with other components, FIG. 7 is a top plan view of a substrate 700 that may be, for example, a printed circuit board or chip module substrate (e.g., a thin-film tile). In the illustrated example, the substrate 700 includes multiple ICs 702a-702d having terminal pads 704 which would be interconnected by conductive vias and/or traces on and/or within the substrate 700 or on the opposite (back) surface of the substrate 700 (to avoid clutter, the surface conductive traces are not shown and not all terminal pads are labelled). The ICs 702a-702d may embody, for example, signal switches, active and/or passive filters, amplifiers (including one or more LNAs), and other circuitry. For example, IC 702b may incorporate a circuit that includes one or more nano-pillars FETs as described in this disclosure.

The substrate 700 may also include one or more passive devices 706 embedded in, formed on, and/or affixed to the substrate 700. While shown as generic rectangles, the passive devices 706 may be, for example, filters, capacitors, inductors, transmission lines, resistors, planar antennae elements, transducers (including, for example, MEMS-based transducers, such as accelerometers, gyroscopes, microphones, pressure sensors, etc.), batteries, etc., interconnected by conductive traces on or in the substrate 700 to other passive devices 706 and/or the individual ICs 702a-702d. The front or back surface of the substrate 700 may be used as a location for the formation of other structures.

Embodiments of the present invention are useful in a wide variety of applications, including (by way of example only) personal electronics (e.g., “smart” watches and fitness wearables), personal computers, tablet computers, wireless network components, televisions, cable system “set top” boxes, radar systems (including phased array and automotive radar systems), cellular telephones, radio frequency (RF) circuits of all types, power systems, power converters, electric vehicles of all types, and test equipment. Examples of RF circuits and systems include (but are not limited to) RF power amplifiers, RF low-noise amplifiers (LNAs), phase shifters, attenuators, antenna beam-steering systems, charge pump devices, RF switches, etc.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G New Radio, 6G, and WiFi (e.g., 802.11a, b, g, ac, ax, be) protocols, as well as other radio communication standards and protocols.

Embodiments of the current invention improve FET R_{ON} resistance and switching speed, as well as more control of ON and OFF states due to the GAA architecture. As a person of ordinary skill in the art will understand, a system architecture is beneficially impacted by utilizing embodiments of the current invention in critical ways, including better range, better reception, lower power, longer battery life, wider bandwidth, etc.

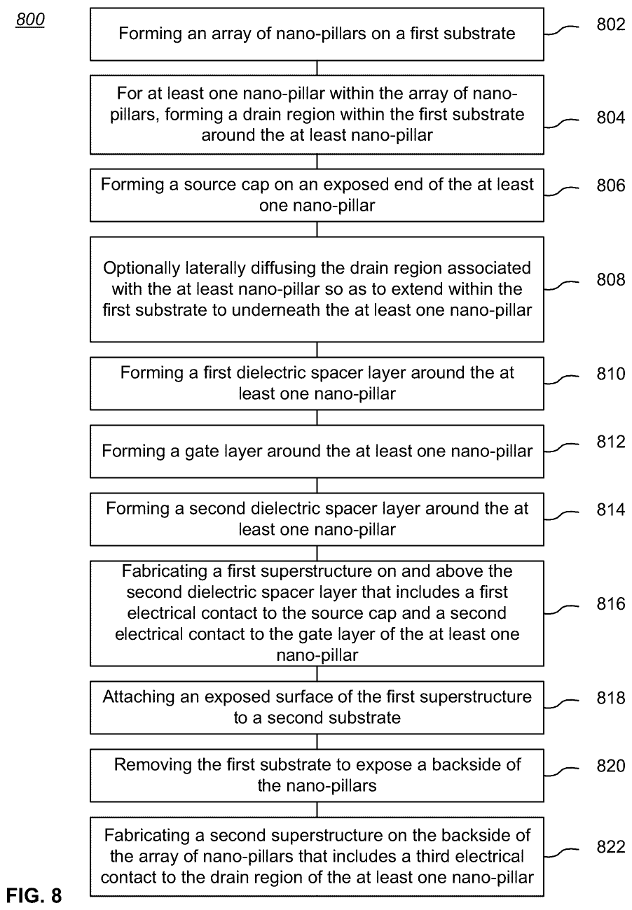

Another aspect of the invention includes methods for fabricating vertical nano-pillar FETs and ICs. For example, FIG. 8 is a process flow chart 800 showing a method for fabricating a vertical nano-pillar FET. The method includes: forming an array of nano-pillars on a first substrate (Block 802); for at least one nano-pillar within the array of nano-pillars, forming a drain region within the first substrate around the at least nano-pillar (Block 804); forming a source cap on an exposed end of the at least one nano-pillar (Block 806); optionally laterally diffusing the drain region associated with the at least nano-pillar so as to extend within the first substrate to underneath the at least one nano-pillar (Block 808); forming a first dielectric spacer layer around the at least one nano-pillar (Block 810); forming a gate layer around the at least one nano-pillar (Block 812); forming a second dielectric spacer layer around the at least one nano-pillar (Block 814); fabricating a first superstructure on and above the second dielectric spacer layer that includes a first electrical contact to the source cap and a second electrical contact to the gate layer of the at least one nano-pillar (Block 816); attaching an exposed surface of the first superstructure to a second substrate (Block 818); removing the first substrate to expose a backside of the nano-pillars (Block 820); and fabricating a second superstructure on the backside of the array of nano-pillars that includes a third electrical contact to the drain region of the at least one nano-pillar (Block 822). A further option is attaching a third substrate to an exposed surface of the second superstructure and removing the second substrate in a DLT process.

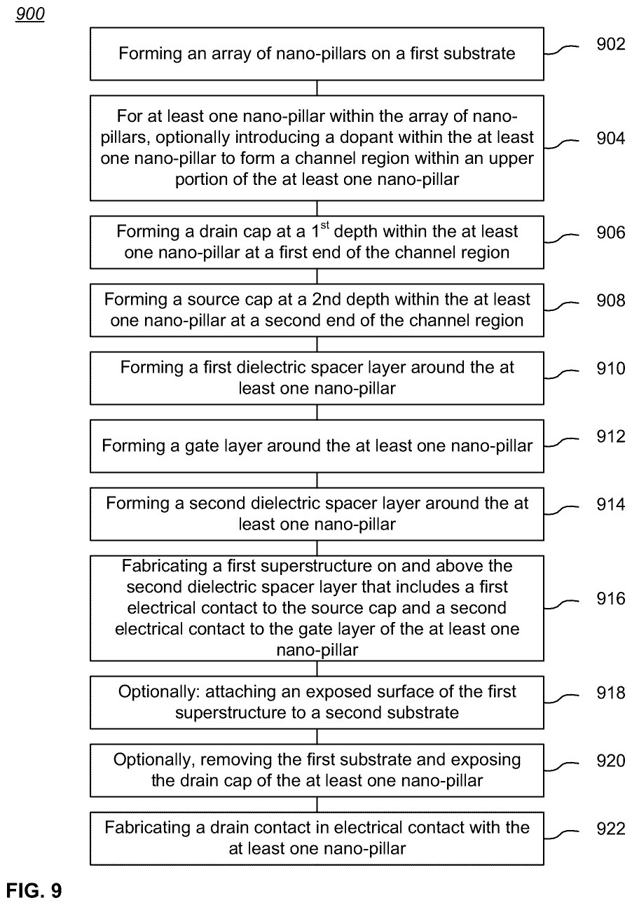

As another example, FIG. 9 is a process flow chart 900 showing a method for fabricating a vertical nano-pillar FET having self-aligned source and drain caps. The method includes: forming an array of nano-pillars on a first substrate (Block 902); for at least one nano-pillar within the array of nano-pillars, optionally introducing a dopant within the at least one nano-pillar to form a channel region within an upper portion of the at least one nano-pillar (Block 904); forming a drain cap at a first depth within the at least one nano-pillar at a first end of the channel region (Block 906); forming a source cap at a second depth within the at least one nano-pillar at a second end of the channel region (Block 908); forming a first dielectric spacer layer around the at least one nano-pillar (Block 910); forming a gate layer around the at least one nano-pillar (Block 912); forming a second dielectric spacer layer around the at least one nano-pillar (Block 914); and fabricating a first superstructure on and above the second dielectric spacer layer that includes a first electrical contact to the source cap and a second electrical contact to the gate layer of the at least one nano-pillar (Block 916).

Optional further steps include attaching an exposed surface of the first superstructure to a second substrate (Block 918); removing the first substrate and exposing the drain cap of the at least one nano-pillar (Block 920); and fabricating a drain contact in electrical contact with the at least one nano-pillar (Block 922). Further optional steps include attaching a third substrate to an exposed backside of the nano-pillars and removing the second substrate in a DLT process.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHZ. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention may be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), BICMOS, LDMOS, BCD, GaAs HBT, GaN HEMT, GaAs pHEMT, MESFET, InP HBT, InP HEMT, FinFET, GAAFET, and SiC-based power device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally may be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus may be performed in an order different from that described. Further, some of the steps described above may be optional. Various activities described with respect to the methods identified above may be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A vertical nano-pillar field-effect transistor (FET), including:
(a) a handle wafer; and
(b) an inverted nano-pillar FET including a superstructure bonded to a surface of the handle wafer.

2. The invention of claim 1, wherein the inverted nano-pillar FET includes:
(a) one or more nano-pillar structures each having a first end, a middle portion, and a second end;
(b) at least one source cap, each source cap in electrical contact with the first end of an associated nano-pillar structure of the one or more nano-pillar structures;
(c) a gate layer surrounding the middle portion of the one or more nano-pillar structures;
(d) a drain region in electrical contact with the second end of the one or more one nano-pillar structures.

3. The invention of claim 2, wherein the drain region is diffused across the second end of one or more nano-pillar structures.

4. The invention of claim 2, wherein the drain region is not diffused across the second end of the one or more nano-pillar structures.

5. The invention of claim 4, further including at least one body contact connected to an undiffused region near the drain-side end of at least one of the one or more nano-pillars.

6. The invention of claim 2, wherein the one or more nano-pillar structures include at least one nanowire structure.

7. The invention of claim 2, wherein the one or more nano-pillar structures include at least one nanosheet structure.

8. The invention of claim 2, wherein the one or more nano-pillar structures include at least two nanosheet structures spanned by a common fin-like nanosheet.

9-20. [Canceled]

21. A vertical nano-pillar field-effect transistor (FET), including:
(a) a handle wafer; and
(b) an inverted nano-pillar FET including a superstructure bonded to a surface of the handle wafer, wherein the inverted nano-pillar FET includes:
(1) one or more nano-pillar structures each having a first end, a middle portion, and a second end;
(2) at least one source cap, each source cap in electrical contact with the first end of an associated nano-pillar structure of the one or more nano-pillar structures;
(3) a gate layer surrounding the middle portion of the one or more nano-pillar structures;
(4) a drain region in electrical contact with the second end of the one or more one nano-pillar structures, wherein the drain region is not diffused across the second end of the one or more nano-pillar structures.

22. The invention of claim 20, wherein the one or more nano-pillar structures include at least one nanowire structure.

23. The invention of claim 20, wherein the one or more nano-pillar structures include at least one nanosheet structure.

24. The invention of claim 20, wherein the one or more nano-pillar structures include at least two nanosheet structures spanned by a common fin-like nanosheet.

25. The invention of claim 20, wherein the one or more nano-pillar structures comprised silicon.

26. The invention of claim 20, further including:
(a) a first dielectric layer formed around the one or more nano-pillars between the at least one source cap and the gate layer; and
(b) a second dielectric layer formed around the one or more nano-pillars between the gate layer and the drain region.

27. A vertical nano-pillar field-effect transistor (FET), including:
(a) a handle wafer; and
(b) an inverted nano-pillar FET including a superstructure bonded to a surface of the handle wafer, wherein the inverted nano-pillar FET includes:
(1) one or more nano-pillar structures each having a first end, a middle portion, and a second end;
(2) at least one source cap, each source cap formed on and in electrical contact with the first end of an associated nano-pillar structure of the one or more nano-pillar structures;
(3) a gate layer surrounding the middle portion of the one or more nano-pillar structures;
(4) at least one drain cap, each drain cap formed on and in electrical contact with the second end of an associated nano-pillar structure of the one or more nano-pillar structures.

28. The invention of claim 27, wherein the one or more nano-pillar structures include at least one nanowire structure.

29. The invention of claim 27, wherein the one or more nano-pillar structures include at least one nanosheet structure.

30. The invention of claim 27, wherein the one or more nano-pillar structures include at least two nanosheet structures spanned by a common fin-like nanosheet.

31. The invention of claim 27, wherein the one or more nano-pillar structures comprised silicon.

32. The invention of claim 27, further including:
(a) a first dielectric layer formed around the one or more nano-pillars between the at least one source cap and the gate layer; and
(b) a second dielectric layer formed around the one or more nano-pillars between the gate layer and the at least one drain cap.

33-39. [Canceled]
